(19) United States
(12) Patent Application Publication
(10) Pub. No.: US 2016/0211491 A1
(43) Pub. Date: Jul. 21, 2016

(54) SEALED TYPE ELECTRICITY STORAGE DEVICE AND METHOD FOR PRODUCING THE SAME

(71) Applicant: SUMITOMO ELECTRIC INDUSTRIES, LTD., Osaka-shi (JP)

(72) Inventors: Mizuo Iwasaki, Osaka-shi (JP); Yasushi Mochida, Osaka-shi (JP)

(21) Appl. No.: 15/023,546

(22) PCT Filed: Sep. 8, 2014
(86) PCT No.: PCT/JP2014/073673

§ 371 Date: Mar. 21, 2016

(30) Foreign Application Priority Data
Oct. 1, 2013 (JP) 2013-206708
Aug. 19, 2014 (JP) 2014-166626

(51) Int. Cl. H01M 2/04; H05K 5/04; H01G 9/00; B23K 26/20; H01M 2/02; H01G 9/145; H05K 5/00; H05K 5/06

(52) U.S. Cl. CPC H01M 2/0439; H05K 5/0004; H05K 5/04; H05K 5/066; B23K 26/206; H01M 2/024; H01G 9/145; H01G 9/0029

(57) ABSTRACT

A method for producing a sealed type electricity storage device includes: a step of preparing a bottomed outer can; a step of preparing a sealing plate having a periphery corresponding to an opening of the outer can, the sealing plate having a first recess in one surface of the periphery and having a tapered second recess in the other surface of the periphery, the first recess being configured to fit into an opening edge portion of the outer can; a step of closing the opening of the outer can with the sealing plate; and a step of welding the opening edge portion of the outer can and the periphery of the sealing plate by irradiating a boundary between the opening edge portion of the outer can and the periphery with a laser beam.

### TECHNICAL FIELD

The present invention relates to a sealed type electricity storage device in which an outer can and a sealing plate are welded and to a method for producing the sealed type electricity storage device. More particularly, the present invention relates to a sealed type electricity storage device in which a weld part has high joint strength and to a method for producing the sealed type electricity storage device.

### BACKGROUND ART

In recent years, environmental issues have received much attention and accelerated development of systems for converting clean energy, such as sunlight and wind power, to electric power and storing electric power as electric energy. Nonaqueous electrolyte secondary batteries and capacitors are known as such electricity storage devices. In particular, sealed type electricity storage devices have grown in demand more than the open type because of their higher electricity storage capacity and smaller size. A sealed type electricity storage device is obtained by, for example, stacking a positive electrode, a negative electrode, and a separator, placing the resultant electrode group and a nonaqueous electrolyte in an outer can, and finally welding a sealing plate to an opening of the outer can.

One of the methods for welding an outer can and a sealing plate is a method as illustrated in the cross-sectional view of FIG. 7a (a so-called vertical welding method), in which a sealing plate 13 is fitted into the opening of an outer can 12, and the sealing plate 13 and the outer can 12 are welded by laser irradiation from a direction substantially perpendicular to the plane direction of the sealing plate 13. According to this method, the working speed can be easily increased and efficient welding can be achieved.

An irradiating laser beam L is absorbed by the surface of a metal material, where light energy is converted into thermal energy. This thermal energy is conducted through the metal material and, as a result, the metal material fuses and then solidifies, whereby the outer can and the sealing plate are welded. That is, laser welding is carried out through the process of heat input→fusing→solidifying→cooling.

The laser welding in this case is keyhole-mode laser welding. Intense metal evaporation occurs on the surface of the metal material irradiated with the laser beam L. Welding proceeds while a deep hole called a keyhole is being formed by repulsive force and thermal energy generated by the metal vapor. Since the depth of the keyhole is proportional to the amount of heat inputted to the metal material, a larger laser output results in a larger keyhole depth. In addition, the depth of the keyhole is considered to substantially correspond to weld penetration depth.

For vertical welding, the weld penetration depth that is substantially as large as at least the thickness of the sealing plate is needed to reduce generation of cracks. To achieve this, it is necessary to increase laser output and increase the amount of heat input. A larger laser output naturally results in a larger thermal energy generated. Excessive laser irradiation may cause fused metal to penetrate through the irradiation surface, which is called burn-through. As a result, a hole is formed in the weld part and the airtightness decreases.

In the process from solidifying to cooling, deformation, such as bulging, of the irradiated part may occur due to the stress associated with shrinkage (shrinkage stress). Since the internal space of an apparatus in which an electricity storage device is to be disposed is predetermined, for example, the external dimensions of the electricity storage device are designed by taking such deformation into account in advance. Therefore, there is also a problem that it is difficult to increase the capacity of the electricity storage device.

One of other welding methods is a so-called horizontal welding method as illustrated in the cross-sectional view of FIG. 7b, in which a sealing plate 13 is fitted onto the edge portion of the opening of an outer can 12 and welded to the outer can 12 by irradiation with a laser beam L in a direction substantially horizontal to the plane direction of the sealing plate 13. Horizontal welding is mainly used for large electricity storage devices because horizontal welding enables a large laser output. However, horizontal welding also has problems such as low airtightness as in vertical welding. Moreover, the production efficiency is low because a laser irradiation apparatus and/or a weld workpiece must be significantly moved during laser irradiation.

In order to solve the problems associated with vertical welding and horizontal welding, for example, a vertical welding method has been proposed as illustrated in the cross-sectional view of FIG. 8, in which a sealing plate 13 is fitted onto the edge portion of the opening of an outer can 12 and welded to the outer can 12 by irradiation with a laser beam L in a direction substantially vertical to the plane direction of the sealing plate 13 (PTL 1). This method involves vertical irradiation with the laser beam L and thus the production efficiency improves.

### CITATION LIST

### Patent Literature

PTL 1: Japanese Unexamined Patent Application Publication No. 2011-171078

### SUMMARY OF INVENTION

### Technical Problem

In the method disclosed in PTL 1, an outer can and a sealing plate are welded by laser irradiation in a direction vertical to the plane direction of the sealing plate 13, rather than performing welding by irradiation with the laser beam L in a direction horizontal to the plane direction of the sealing plate 13. Therefore, a fitting portion of a sealing plate (a flange 7 in PTL 1) is as thin as, for example, 0.5 mm or less. When the fitting portion has such a small thickness, the amount of metal contributing to welding is too small to provide sufficient joint strength.

### Solution to Problem

An aspect of the present invention is directed to a method for producing a sealed type electricity storage device including: a step of preparing a bottomed outer can that accommodates an electrode group; a step of preparing a sealing plate having a periphery corresponding to an opening of the outer can, the sealing plate having a first recess in one surface of the periphery and having a tapered second recess in the other surface of the periphery, the first recess being configured to fit into an opening edge portion of the outer can; a step of closing the opening of the outer can with the sealing plate by fitting the first recess into the opening edge portion of the outer can; and a step of welding the opening edge portion of the outer can and the periphery of the sealing plate by irradiating the boundary between the opening edge portion of the outer can and the periphery of the sealing plate with a laser beam at an angle of 15° to 75° with respect to the thickness direction of the sealing plate.

Another aspect of the present invention is directed to a sealed type electricity storage device including an electrode group, a bottomed outer can that accommodates the electrode group, and a sealing plate having a periphery corresponding to an opening of the outer can. An edge portion of the outer can and the periphery are welded to form a fusion part. In the cross section of the fusion part parallel to the thickness direction of a side wall of the outer can and parallel to the thickness direction of the sealing plate, the width Wⱼ of the fusion part at the initial position of the opening edge portion of the outer can and the maximum distance d from the initial position to the interface between the fusion part and a non-fusion part satisfy 3.5≦Wⱼ/d.

### Advantageous Effects of Invention

According to the above description, the opening edge portion of the outer can and the periphery of the sealing plate can be welded at a low laser output and the sealed type electricity storage device having sufficient joint strength between the outer can and the sealing plate can be obtained.

### BRIEF DESCRIPTION OF DRAWINGS

FIG. 1 is a perspective view of a sealed type electricity storage device according to an embodiment of the present invention in which an outer can and a sealing plate (a combination of which may be referred to as a case hereinafter) before welding are partially cut out.

FIG. 2 is a schematic longitudinal cross-sectional view taken along line II-II in FIG. 1.

FIG. 3a is an enlarged cross-sectional view of the upper edge portion of a side wall of the outer can and the surrounding area.

FIG. 3b is an enlarged cross-sectional view of the periphery of the sealing plate and the surrounding area.

FIG. 4 is an enlarged cross-sectional view of a fitting part between the sealing plate and the outer can.

FIG. 5 is a cross-sectional view schematically illustrating how heat diffuses in FIG. 4.

FIG. 6 is a cross-sectional view schematically illustrating the shape after welding in FIG. 4.

FIG. 7a is a cross-sectional view schematically illustrating a laser welding method according to the related art.

FIG. 7b is a cross-sectional view schematically illustrating a laser welding method according to the related art.

FIG. 8 is a cross-sectional view schematically illustrating another laser welding method according to the related art.

FIG. 9 is a cross-sectional view schematically illustrating a laser welding method according to a reference embodiment.

FIG. 10 is a cross-sectional view schematically illustrating how heat diffuses in FIG. 9.

FIG. 11 is a cross-sectional view schematically illustrating the shape after welding in FIG. 9.

FIG. 12a is an enlarged photograph (at a magnification of 18×) according to Example 1.

FIG. 12b is a traced drawing of FIG. 12a.

FIG. 13a is an enlarged photograph (at a magnification of 18×) according to Example 2.

FIG. 13b is a traced drawing of FIG. 13a.

FIG. 14a is an enlarged photograph (at a magnification of 18×) according to Comparative Example 1.

FIG. 14b is a traced drawing of FIG. 14a.

FIG. 15a is an enlarged photograph (at a magnification of 18×) according to Comparative Example 2.

FIG. 15b is a traced drawing of FIG. 15a.

FIG. 16a is an enlarged photograph (at a magnification of 18×) according to Reference Example 1.

FIG. 16b is a traced drawing of FIG. 16a.

### DESCRIPTION OF EMBODIMENTS

As illustrated in the cross-sectional view of FIG. 9, a laser welding method other than the above methods may include fitting the sealing plate 13 onto the opening edge portion of the outer can 12 such that the edge portion is exposed, and welding the outer can 12 and the sealing plate 13 by irradiation with a laser beam L in an oblique direction. Since the boundary between the edge portion of the outer can 12 and the sealing plate 13 is irradiated with the laser beam L in this case, the protrusion of the irradiated part does not significantly affect the external dimensions, which is an advantage of this method. However, it is difficult for this method to provide a sufficient weld penetration depth at a low laser output. The reason is probably as follows.

Irradiating light energy is absorbed by the surfaces and converted into thermal energy. Heat is conducted through metals constituting the outer can 12 and the sealing plate 13 and diffuses. When the outer can 12 and the sealing plate 13 are made of the same material, heat diffuses radially and uniformly. Since metal has higher thermal conductivity than air, heat is conducted to the metal part rather than being radiated outside the outer can 12 and the sealing plate 13. Therefore, as illustrated in FIG. 10, heat tends to diffuse in the inner direction of the side wall of the outer can 12 and in the upper surface direction of the sealing plate 13.

When heat diffuses in the inner direction of the side wall of the outer can 12 and in the upper surface direction of the sealing plate 13, the metals in these parts fuse. However, these fused parts do not contribute much to joint strength because these fused parts are distant from the fitting part. The joint strength is affected mainly by the fused metal area on the joint surface. To increase the amount of metal fused in the fitting part and increase the fusion area on the joint surface by conducting heat to the fitting part, laser irradiation at a high output is needed. A high laser output generates problems such as low airtightness as in the related art. Therefore, it is desirable to obtain sufficient joint strength at a low laser output.

### DESCRIPTION OF EMBODIMENTS

First, features of embodiments of the present invention will be listed and described.

A method for producing a sealed type battery according to an aspect of the present invention is (1) a method for producing a sealed type electricity storage device including: a step of preparing a bottomed outer can that accommodates an electrode group; a step of preparing a sealing plate having a periphery corresponding to an opening of the outer can, the sealing plate having a first recess in one surface of the periphery and having a tapered second recess in the other surface of the periphery, the first recess being configured to fit into an edge portion of the outer can corresponding to the opening (opening edge portion); a step of closing the opening of the outer can with the sealing plate by fitting the first recess into the edge portion of the outer can; and a step of welding the edge portion of the outer can and the periphery of the sealing plate by irradiating the boundary between the edge portion of the outer can and the periphery with a laser beam at an angle of 15° to 75° with respect to the thickness direction of the sealing plate. Since the tapered second recess is formed in one surface of the periphery of the sealing plate, the thermal energy from the laser irradiation is more efficiently conducted to the joint surface, which contributes to the joint strength, than to the upper portion of the sealing plate, which does not contribute to the joint strength, and therefore the joint strength improves.

(2) The second recess is preferably formed at an angle of 15° to 75° with respect to the thickness direction of the sealing plate. This is because such a second recess can reduce dispersion of thermal energy and permits the sealing plate to have a sufficient thickness.

(3) The thickness (Tₜ) of the sealing plate is preferably larger than the sum of the length (T_{A}) of the first recess in the thickness direction of the sealing plate and the length (T_{B}) of the second recess in the thickness direction of the sealing plate. This is because the erect portion of the sealing plate is formed at the boundary between the sealing plate and the edge portion of the opening of the outer can, so that it is easy to direct a laser beam to a specified irradiation position. Moreover, a large amount of metal that can fuse can be ensured at and near the boundary and therefore the joint strength improves.

Sealed type electricity storage devices have been recently used for the storage of electricity in vehicles or in solar cells and wind power generation, and hence there is a need for large electricity storage devices. In such cases, it is necessary to increase the joint strength between an outer can and a sealing plate and to increase the strength of the outer can and the sealing plate by increasing the thickness of side walls of the outer can and the sealing plate.

(4) The thickness (Tₜ) of the sealing plate is preferably 0.5 to 3 mm and the thickness (Wₜ) of a side wall of the outer can is preferably 0.5 to 3 mm. This is because the entire strength of the sealed type battery can be maintained high and the sealed type battery can be reduced in weight.

(5) The distance (WD) from the boundary to the outer surface of the side wall in the opening edge portion of the outer can is preferably larger than the beam radius of a laser beam. This is because the change in the external shape of the outer can by welding is suppressed.

(6) The laser beam used in irradiation preferably has a beam radius of 0.1 to 0.5 mm. This is because such irradiation has a small effect on the performance of the electricity storage device and the change in the external shape of the outer can is suppressed with such irradiation.

A sealed type battery according to an aspect of the present invention is (7) a sealed type electricity storage device including an electrode group, a bottomed outer can that accommodates the electrode group, and a sealing plate having a periphery corresponding to an opening of the outer can. An edge portion of the outer can and the periphery are welded to form a fusion part. In the cross section of the fusion part parallel to the thickness direction of a side wall of the outer can and parallel to the thickness direction of the sealing plate, the width Wⱼ of the fusion part at the initial position of the opening edge portion of the outer can and the maximum distance d from the initial position to the interface between the fusion part and a non-fusion part satisfy 3.5≦Wⱼ/d. Since the fusion part has a large width, the joint strength is high.

### Detailed Description of Embodiments of Present Invention

Specific examples of embodiments of the present invention will be described below. The present invention is not limited to these examples. The scope of the present invention is indicated by the claims and is intended to include all modifications within the meaning and range of equivalency of the claims.

### [Method for Producing Sealed Type Electricity Storage Device]

A sealed type electricity storage device is produced by a production method including: (i) a step of preparing a bottomed outer can that accommodates an electrode group; (ii) a step of preparing a sealing plate having a periphery corresponding to an opening of the outer can, the sealing plate having a first recess in one surface of the periphery and having a tapered second recess in the other surface of the periphery, the first recess being configured to fit into an edge portion of the outer can corresponding to the opening; (iii) a step of closing the opening of the outer can with the sealing plate by fitting the first recess into the opening edge portion of the outer can; and (iv) a step of welding the opening edge portion of the outer can and the periphery of the sealing plate by irradiating the boundary between the opening edge portion of the outer can and the periphery with a laser beam traveling from the periphery toward the center of the sealing plate at an angle of 15° to 75° with respect to the thickness direction of the sealing plate.

Examples of the electricity storage device may include, but are not limited to, capacitors, such as lithium-ion capacitors and sodium-ion capacitors, and nonaqueous electrolyte secondary batteries, such as lithium-ion secondary batteries and sodium-ion secondary batteries.

Each step will be described below.

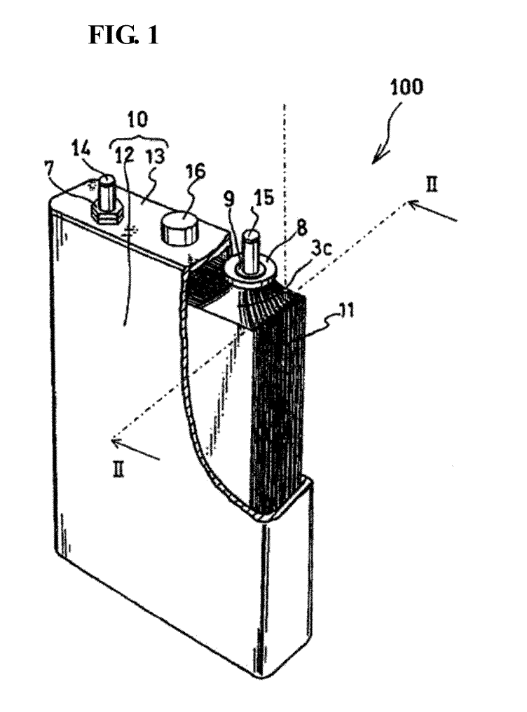

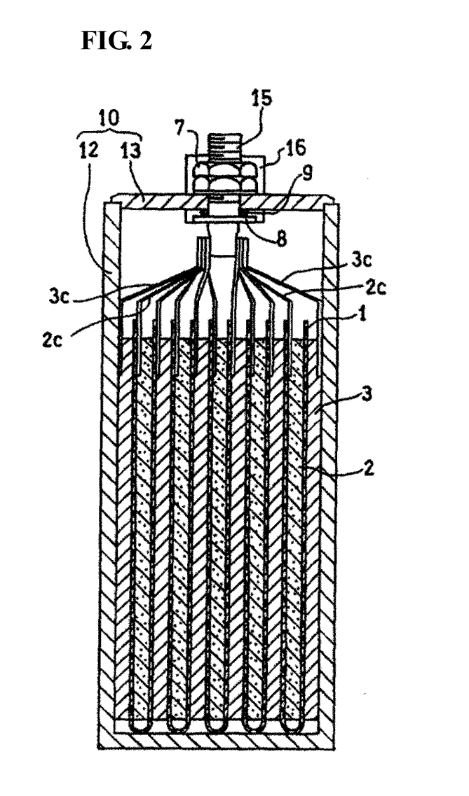

(i) First, a bottomed outer can for accommodating an electrode group is prepared. As illustrated in FIG. 1 or FIG. 2, an electrode group 11 includes multiple positive electrodes 2, multiple negative electrodes 3, and multiple separators 1 each interposed between the positive electrode 2 and the negative electrode 3. FIG. 2 illustrates a stacked type electricity storage device in which multiple positive electrodes 2 and multiple negative electrodes 3 that have a rectangular shape are stacked in an alternate manner. However, a spiral-wound type electricity storage device may be provided in which a stacked body including strip-shaped positive electrodes, strip-shaped negative electrodes, and strip-shaped separators is spirally wound. An outer can 12 accommodates the electrode group 11 including the positive electrodes 2, the negative electrodes 3, and the separators 1. The electrode group 11 may be impregnated with an electrolyte (not shown) before the electrode group 11 is accommodated in the outer can 12.

The outer can 12 has a bottom and side walls, and the upper edge portions (opening edge portions) of the side walls form an opening. Examples of the shape of the opening may include, but are not limited to, a rectangular shape and a circular shape. FIGS. 1 and 2 illustrate an outer can having a rectangular opening, which is commonly used.

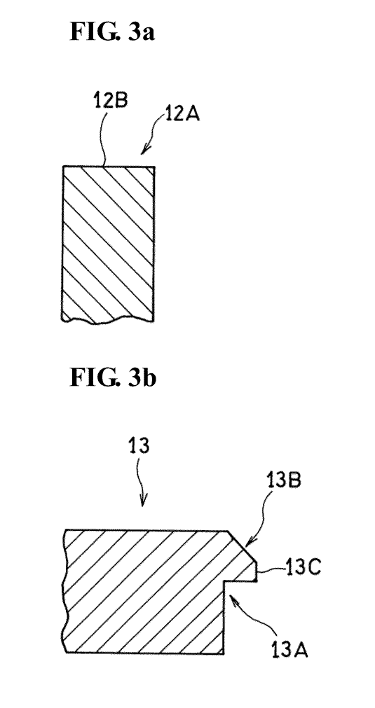

FIG. 3a is an enlarged cross-sectional view of an opening edge portion 12A of the outer can 12 and the surrounding area. The opening edge portion 12A of the outer can 12 has a shape into which a first recess of the sealing plate 12 will fit. In FIG. 3a, the opening edge portion 12A extends upward, and an end face 12B of the opening edge portion 12A has an upward-facing flat surface. A first recess 13A (see FIG. 3b) of the sealing plate will fit into a portion of the end face 12B. The opening edge portion 12A is not limited to this shape. For example, the opening edge portion 12A may bend toward the center of the opening and thus may have a surface that is parallel or substantially parallel to the bottom of the outer can 12. In this case, the first recess 13A of the sealing plate will fit onto the surface that is parallel or substantially parallel to the bottom of the outer can 12.

The outer can 12 is preferably made of metal. Examples of metals used may include aluminum, aluminum alloys, and iron. Aluminum alloys are alloys of aluminum with, for example, copper, manganese, silicon, magnesium, zinc, or nickel. The thickness (Wt) of the outer wall of the outer can 12 is preferably 0.5 to 3 mm from the viewpoint of strength and light-weightness. In particular, the thickness is preferably 0.6 to 1.2 mm.

The size of the outer can 12 is not limited and may be appropriately set according to, for example, a desired performance of the electricity storage device. The shape of the outer can 12 is not limited either and an example of the shape may be a prismatic shape or a cylindrical shape. In an embodiment of the present invention, a large prismatic outer can having a size of 5 to 50 mm×50 to 200 mm×50 to 200 mm may be used as an example. Although a typical prismatic electricity storage device is illustrated in FIG. 2, the electricity storage device is not limited to this.

(ii) Next, a sealing plate 13 for closing the opening of the outer can 12 is prepared. The sealing plate 13 is preferably made of metal. Examples of the metal used may include the same metals as those for the outer can 12, such as aluminum, aluminum alloys, and iron. The material of the sealing plate 13 is preferably the same as that of the outer can 12 from the viewpoint of cost and ease of welding. The thickness (Tₜ) of the sealing plate 13 is preferably 0.5 to 3 mm from the viewpoint of strength and light-weightness. In particular, the thickness is preferably 0.8 to 2 mm. Furthermore, the thickness (Tₜ) of the sealing plate 13 is preferably larger than the thickness (Wₜ) of the side walls of the outer can 12 from the viewpoint of strength.

The size and shape of the sealing plate 13 are not limited and may be appropriately set according to the size and shape of the outer can 12. The sealing plate 13 as viewed from above is larger than the opening of the outer can 12 and smaller than the area formed by the outer surfaces of the side walls in the opening edge portion 12A. In an embodiment of the present invention, a rectangular sealing plate having a size of 5 to 50 mm×50 to 200 mm×0.5 to 3 mm may be used as an example.

FIG. 3b is an enlarged cross-sectional view of the periphery of the sealing plate 13 and the surrounding area. The first recess 13A is formed in one surface of the periphery of the sealing plate 13. The first recess 13A will fit into the opening edge portion 12A of the outer can 12 such that the sealing plate 13 is fixed to cover the opening of the outer can 12. The shape of the first recess 13A is preferably, but not necessarily, a shape that is to closely fit into the opening edge portion 12A of the outer can 12. For example, as illustrated in FIG. 3b, a right-angled recess is preferred.

The size of the first recess 13A is not limited. For example, for a right-angled recess, the length (T_{A}) of the first recess 13A in the thickness direction is preferably 0.5 to 2.5 mm and the length (W_{A}) of the first recess 13A in the horizontal direction is preferably 0.5 to 2.5 mm because the sealing plate 13 will securely be fixed. The first recess 13A can be formed by machining or press working, but the formation method is not limited.

The sealing plate 13 has a tapered second recess (hereinafter referred to simply as a second recess 13B) obtained by chamfering the other surface of the periphery, namely, a surface opposite to the surface having the first recess 13A. The second recess 13B can be formed by machining or press working, but the formation method is not limited. The first recess 13A and the second recess 13B may simultaneously be formed by press working or may be formed by separate processes.

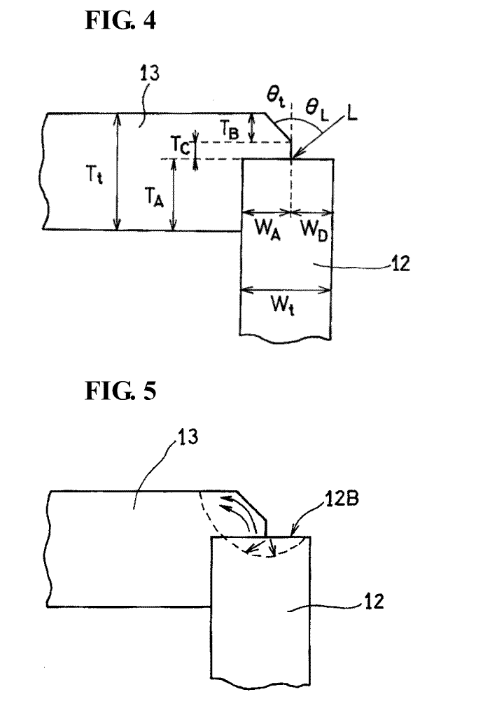

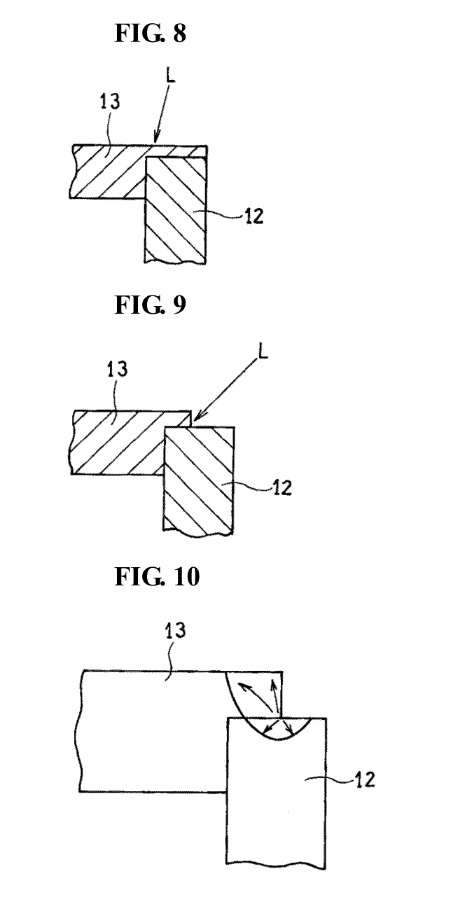

FIG. 4 illustrates a cross section of a fitting part between the sealing plate 13 and the outer can 12. In FIG. 4, hatching that indicates a cross section is omitted for convenience. The same applies to the cross-sectional views except for FIG. 2, FIG. 7a, FIG. 7b, FIG. 8, and FIG. 9.

As the taper angle (θₜ) of the second recess 13B with respect to the thickness direction of the sealing plate 13 increases, the length (T_{B}) of the second recess 13B in the thickness direction of the sealing plate 13 decreases. That is, the thickness (Tₜ) of the sealing plate 13 decreases accordingly. As the taper angle (θₜ) decreases, the length (T_{B}) of the second recess 13B increases. That is, the thickness (Tₜ) of the sealing plate 13 increases accordingly. To increase the thickness (Tₜ) of the sealing plate 13 (to increase the entire strength of the case), a smaller taper angle (θₜ) is preferred. To improve the joint strength at a low laser output, a larger taper angle (θₜ) is preferred.

To increase the thickness (Tₜ) of the sealing plate 13 sufficiently while improving the joint strength, the taper angle (θₜ) of the second recess 13B is preferably 15° to 75°. In particular, the taper angle (θₜ) is preferably 40° to 50°.

The length (T_{B}) of the second recess 13B in the thickness direction of the sealing plate 13 is preferably smaller than the length obtained by subtracting the length (T_{A}) of the first recess 13A in the thickness direction of the sealing plate 13 from the thickness (Tₜ) of the sealing plate. In other words, the thickness (Tₜ) of the sealing plate 13 is preferably larger than the sum of the length (T_{A}) of the first recess 13A and the length (T_{B}) of the second recess 13B. In this case, an erect portion 13C (see FIG. 3b) of the sealing plate 13 is formed at the boundary between the opening edge portion 12A and the sealing plate 13, so that it is easy to direct a laser beam to a specified irradiation position.

The erect portion 13C of the sealing plate 13 fuses by laser welding described below and contributes to joining the outer can 12 and the sealing plate 13. That is, because of the erect portion 13C, it is possible to obtain a large amount of metal that can fuse at and near the joint portion and thus the joint strength is further improved.

The height (T_{C}) of the erect portion 13C is preferably 1/20 to ⅓ of the thickness (Tₜ) of the sealing plate 13 from the viewpoint of easy irradiation with a laser beam L and joint strength. In particular, the height (T_{C}) of the erect portion 13C is preferably about ⅕ of the thickness (Tₜ) of the sealing plate 13. The height (T_{C}) of the erect portion 13C is preferably 0.1 to 0.6 mm.

The distance (W_{D}) from the boundary between the opening edge portion 12A and the sealing plate 13 (the starting point of the erect portion 13C) to the outer wall surface of the opening edge portion 12A is preferably larger than the beam radius of the laser beam L. The boundary between the opening edge portion 12A and the sealing plate 13 (the starting point of the erect portion 13C) is irradiated with the laser beam L. When the distance (WD) is larger than the beam radius of the laser beam L, a fused metal can be inhibited from flowing out of the outer can 12 and thus it is possible to suppress the change in external shape.

(iii) Next, the opening of the outer can 12 is closed with the sealing plate 13 by fitting the first recess 13A into the opening edge portion 12A. The first recess 13A allows the sealing plate 13 to be fixed onto the opening edge portion 12A.

(iv) The opening edge portion 12A and the periphery of the sealing plate 13 are welded by irradiating the boundary between the opening edge portion 12A and the sealing plate 13 with the laser beam L at an angle of 15° to 75° with respect to the thickness direction of the sealing plate 13. Finally, an electrolyte is introduced through a safety valve 16 or the like.

The irradiation angle (θ_{L}) of the laser beam L with respect to the thickness direction of the sealing plate 13 is preferably 40° to 50° from the viewpoint of production efficiency and joint strength. The irradiation angle (θ_{L}) can be set independently of the taper angle (θₜ) of the second recess 13B.

The laser beam L used in irradiation preferably has a beam radius of 0.1 to 0.5 mm. When the beam radius is in this range, the effect of the irradiation on the electrode group 11 accommodated in the outer can 12 can be minimized. The travel speed of the laser beam L is preferably, but not necessarily, 3 to 100 mm/sec from the viewpoint of joint strength and production efficiency. The output of the laser beam L is not limited either because the output depends on the type of laser. For example, for a fiber laser, the output is preferably 0.3 to 5 kW and more preferably 0.8 to 5 kW.

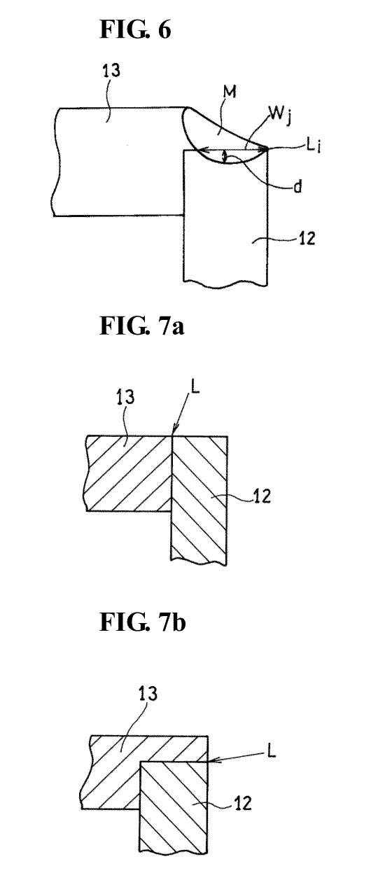

FIG. 5 is a cross-sectional view schematically illustrating how heat generated by laser beam irradiation diffuses. This cross-sectional view is a view of the cross section parallel both to the thickness direction of a side wall of the outer can 12 and to the thickness direction of the sealing plate 13. Because a portion of the outer can 12 and a portion of the sealing plate 13 fuse during welding, the appearance thereof changes as illustrated in FIG. 6.

As illustrated in FIG. 5, the heat generated by laser beam irradiation and absorbed by the outer can 12 and the sealing plate 13 is radially transmitted into the metal from the irradiation point. When the heat reaches the second recess 13B, the heat is then transmitted in the inner direction of the sealing plate 13. The second recess 13B reduces the transmission of the heat to the sealing plate 13 and increases the transmission of the heat to the outer can 12. In the outer can 12, the heat is radially transmitted and the fusion part also spreads in the thickness direction of the outer can 12. Compared with FIG. 10 having no second recess, the fusion part extends on the further left side in the drawing. The fusion part is a region M (see FIG. 6) formed as a metal constituting the outer can 12 and a metal constituting the sealing plate 13 undergo fusion with external energy and solidification in a fitting part between the outer can 12 and the sealing plate 13.

FIG. 6 is a schematic cross-sectional view of the region M and the surrounding area after laser welding. FIG. 6 is a view of the cross section parallel both to the thickness direction of a side wall of the outer can 12 and to the thickness direction of the sealing plate 13, as in FIG. 5. The position of a surface of the opening edge portion 12A before welding, namely, the surface onto which the sealing plate 13 fits, is referred to as an initial position (Lᵢ). In FIG. 6, the initial position (Lᵢ) corresponds to the end face 12B of the opening edge portion of the outer can in FIG. 3a.

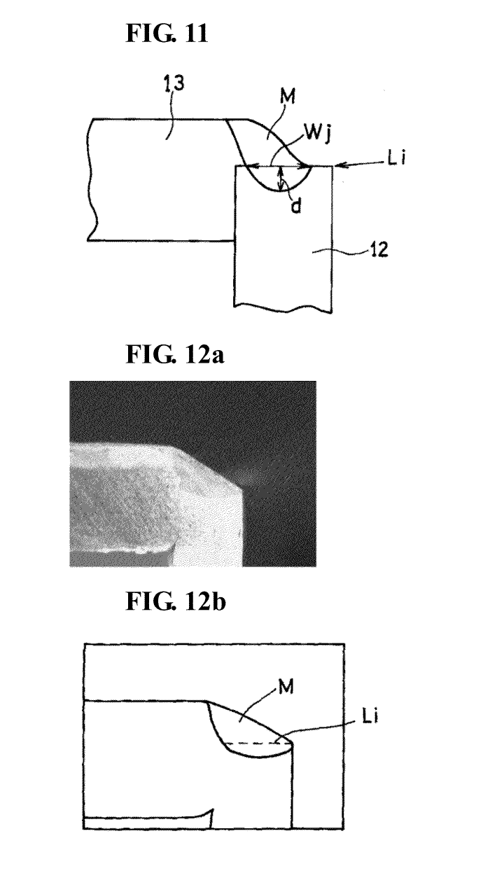

The second recess 13B changes the direction of the transmission of heat. For example, in the region M in the side wall of the outer can 12, the maximum distance from the initial position (Lᵢ) to the interface between the fusion part and the non-fusion part (hereinafter referred to simply as a fusion depth (d)) is smaller than that in FIG. 11 having no second recess 13B.

The heat generated by irradiation with the laser beam L and absorbed by the outer can 12 and the sealing plate 13 is radially transmitted to the metals constituting the outer can 12 and the sealing plate 13 from the irradiation point. As illustrated in FIG. 10, when the sealing plate 13 has no second recess 13B, a large amount of heat is transmitted upward in the thickness direction of the sealing plate 13 and a small amount of heat is transmitted to the outer can 12. In the sealing plate 13, the transmission of heat in the inner direction decreases. For the heat transmitted to the outer can 12, the transmission in the depth direction increases and the transmission in the thickness direction of the outer can decreases. The reason for this is not clear. As a result, the fusion depth (d) increases and the width (Wⱼ) of the fusion part at the initial position (Lᵢ) decreases.

In contrast, because of the second recess 13B, the width (Wⱼ) of the fusion part at the initial position (Lᵢ) increases and the fusion depth (d) decreases. Since the joint strength is mainly affected by the fusion area on the joint surface, a large width (Wⱼ) of the fusion part results in an improved joint strength. A small fusion depth (d) results in a small effect on the electrode group 11 accommodated in the outer can 12.

The ratio (Wⱼ/d) of the width (Wⱼ) of the fusion part to the fusion depth (d) is 3.5 or more. A ratio (Wⱼ/d) of less than 3.5 fails to provide sufficient joint strength. A ratio (Wⱼ/d) of less than 3.5 means that the heat absorbed by the outer can 12 is transmitted toward the electrode group 11 accommodated in the outer can 12, not toward the direction where the width of the fusion part increases. The Wⱼ/d is preferably 4.0 or more. In the measurement of the width (Wⱼ) of the fusion part of the outer can 12 and the sealing plate 13 and the fusion depth (d), a cross section of a flat portion rather than a corner portion is observed for a prismatic case. This is because the manner in which heat is transmitted in the corner portion is considered to be different from that in the flat portion.

The width (Wⱼ) of the fusion part is preferably 0.6 to 0.8 mm. A desired joint strength is readily obtained with a width (Wⱼ) of the fusion part in this range. When an outer can 38 mm in width, 112 mm in length, and 150 mm in height and a sealing plate are welded, the joint strength is preferably sufficient to prevent the weld part from being fractured at an internal pressure of 1.5 MPa in the joint strength test described below. The fusion depth (d) is preferably 0.2 to 0.4 mm.

A typical device used for laser welding includes a laser oscillator, a beam-condensing unit, an optical path, a drive unit, and an assist gas feeder. A laser beam emitted from the laser oscillator travels by way of mirror transmission or through an optical path such as an optical fiber, is condensed into a suitable size by the beam-condensing unit including a parabolic reflector and a lens, and is applied to a weld workpiece. At this time, argon gas, helium gas, nitrogen gas, or the like is sprayed as a shielding gas in order to avoid oxidation and spatter of/on the metal weld part.

The laser is not limited to any particular type. Examples of the laser include solid-state lasers using ruby, glass, or YAG as a medium, semiconductor lasers using GaAs or InGaAsP as a medium, gas lasers using He—Ne, Ar, an excimer, CO₂, or the like as a medium, liquid lasers using an organic solvent, and fiber lasers.

### [Electrolyte]

The electrolyte is not limited and may be selected depending on desired performance or the like. In particular, molten salts are preferably used as an electrolyte because molten salts have high heat resistance and are less affected by laser welding. In particular, a sodium molten salt is preferably used as an electrolyte from the viewpoint of cost. The case where a sodium molten salt is used as an electrolyte is illustrated below, but the electrolyte is not limited to this sodium molten salt.

A molten salt electrolyte contains 90 mass % or more of an ionic liquid including a sodium salt. The ionic liquid is in the form of a liquid in the operational temperature range of the electricity storage device. The molten salt electrolyte has advantages of high heat resistance and non-combustibility. Therefore, the molten salt electrolyte preferably contains as little components other than the ionic liquid as possible. In particular, the molten salt electrolyte preferably contains 95 to 100 mass % of the ionic liquid including a sodium salt. However, the molten salt electrolyte may contain various additives and organic solvents in amounts in which the heat resistance and the non-combustibility are significantly impaired. The ionic liquid is a liquid including an anion and a cation.

A sodium salt is a salt of a sodium ion and an anion. The anion is preferably a polyatomic anion. Examples of the polyatomic anion may include PF₆⁻, BF₄⁻, ClO₄⁻, and anions represented by [(R¹SO₂)(R²SO₂)]N⁻ (R¹ and R² each independently represent F or CₙF₂ₙ₊₁ where 1≦n≦5) (hereinafter also referred to as bis(sulfonyl)amide anions). Of these, bis(sulfonyl)amide anions are preferred from the viewpoint of the heat resistance of the electricity storage device and the ionic conductivity.

Specific examples of bis(sulfonyl)amide anions include a bis(fluorosulfonyl)amide anion, a (fluorosulfonyl)(perfluoroalkylsulfonyl)amide anion, and a bis(perfluoroalkylsulfonyl)amide anion (PFSA⁻). The number of carbon atoms of the perfluoroalkyl group is, for example, one to five, more preferably one or two, and still more preferably one. These anions may be used alone or in combination of two or more.

Preferred examples of such bis(sulfonyl)amide anions include a bis(fluorosulfonyl)amide anion (FSA), a bis(trifluoromethylsulfonyl)amide anion (TFSA⁻), a bis(pentafluoroethylsulfonyl)amide anion, and a (fluorosulfonyl)(trifluoromethylsulfonyl)amide anion.

Specific examples of the sodium salt include a salt of a sodium ion and FSA⁻ (Na-FSA) and a salt of a sodium ion and TFSA⁻ (Na-TFSA).

The ionic liquid is preferably a mixture of a sodium salt and an ionic liquid other than the sodium salt in order to decrease the melting point of the ionic liquid and also the melting point of the molten salt electrolyte.

That is, the ionic liquid preferably contains, as a salt other than the sodium salt, a salt of an anion, such as PF₆⁻, BF₄⁻, ClO₄⁻, or a bis(sulfonyl)amide anion, and a cation other than a sodium ion. As a result, the heat resistance of the electricity storage device and the ionic conductivity increase. Of such anions, a bis(sulfonyl)amide anion is preferred. Specific examples of bis(sulfonyl)amide anions are the same compounds as those described above.

Examples of cations other than a sodium ion include organic cations and alkali metal cations other than a sodium cation. Examples of organic cations may include nitrogen-containing cations; sulfur-containing cations; and phosphorus-containing cations. Examples of nitrogen-containing cations may include cations derived from aliphatic amines, alicyclic amines, and aromatic amines (e.g., quaternary ammonium cations), and organic cations having a nitrogen-containing heterocycle (e.g., cations derived from cyclic amines).

Examples of quaternary ammonium cations may include tetraalkylammonium cations (e.g., tetra C₁₋₁₀ alkylammonium cations), such as a tetramethylammonium cation, an ethyltrimethylammonium cation, a hexyltrimethylammonium cation, a tetraethylammonium cation (TEA⁺), and a triethylmethylammonium cation (TEMA⁺).

Examples of sulfur-containing cations may include tertiary sulfonium cations, for example, trialkylsulfonium cations (e.g., tri C₁₋₁₀ alkylsulfonium cations), such as a trimethylsulfonium cation, a trihexylsulfonium cation, and a dibutylethylsulfonium cation.

Examples of phosphorus-containing cations include quaternary phosphonium cations, for example, tetraalkylphosphonium cations (e.g., tetra C₁₋₁₀ alkylphosphonium cations), such as a tetramethylphosphonium cation, a tetraethylphosphonium cation, and a tetraoctylphosphonium cation; and alkyl(alkoxyalkyl)phosphonium cations (e.g., tri C₁₋₁₀ alkyl(C₁₋₅ alkoxy-C₁₋₅ alkyl)phosphonium cations), such as a triethyl(methoxymethyl)phosphonium cation, a diethylmethyl(methoxymethyl)phosphonium cation, and a trihexyl(methoxyethyl)phosphonium cation. In alkyl(alkoxyalkyl)phosphonium cations, the total number of the alkyl group and the alkoxyalkyl group bonded to the phosphorus atom is four and the number of the alkoxyalkyl group is preferably one or two.

The number of carbon atoms of the alkyl group bonded to the nitrogen atom of a quaternary ammonium cation, to the sulfur atom of a tertiary sulfonium cation, or to the phosphorus atom of a quaternary phosphonium cation is preferably one to eight, more preferably one to four, and still more preferably one, two, or three.

An organic cation here is preferably an organic cation having a nitrogen-containing heterocycle. An ionic liquid including an organic cation having a nitrogen-containing heterocycle is a prospective molten salt electrolyte due to its high heat resistance and low viscosity. Examples of the nitrogen-containing heterocyclic backbone of the organic cation may include 5-8 membered heterocycles having one or two nitrogen atoms as constituent atoms of the rings, such as pyrrolidine, imidazoline, imidazole, pyridine, and piperidine; and 5-8 membered heterocycles having one or two nitrogen atoms and other heteroatoms (e.g., an oxygen atom and a sulfur atom) as constituent atoms of the rings, such as morpholine.

The nitrogen atom that is a constituent atom of the ring may be substituted by an organic group, such as an alkyl group. Examples of the alkyl group may include C₁₋₁₀ alkyl groups, such as a methyl group, an ethyl group, a propyl group, and an isopropyl group. The number of carbon atoms in the alkyl group is preferably one to eight, more preferably one to four, and still more preferably one, two, or three.

Of organic cations having a nitrogen-containing heterocycle, organic cations having a pyrrolidine backbone are prospective molten salt electrolytes due to their high heat resistance and low production costs. In organic cations having a pyrrolidine backbone, one nitrogen atom on the pyrrolidine ring preferably has two of the above alkyl groups. In organic cations having a pyridine backbone, one nitrogen atom on the pyridine ring preferably has one of the above alkyl groups. In organic cations having an imidazole backbone, two nitrogen atoms on the imidazole ring each preferably have one of the above alkyl groups.

Specific examples of organic cations having a pyrrolidine backbone include a 1,1-dimethylpyrrolidinium cation, a 1,1-diethylpyrrolidinium cation, a 1-ethyl-1-methylpyrrolidinium cation, a 1-methyl-1-propylpyrrolidinium cation (MPPY⁺), a 1-methyl-1-butylpyrrolidinium cation (MBPY⁺), and a 1-ethyl-1-propylpyrrolidinium cation. Of these organic cations, pyrrolidinium cations having a methyl group and a C₂₋₄ alkyl group, such as MPPY⁺ and MBPY⁺, are preferred because they particularly have high electrochemical stability.

Specific examples of organic cations having a pyridine backbone include 1-alkylpyridinium cations, such as a 1-methylpyridinium cation, a 1-ethylpyridinium cation, and a 1-propylpyridinium cation. Of these organic cations, pyridinium cations having a C₁₋₄ alkyl group are preferred.

Specific examples of organic cations having an imidazole backbone include a 1,3-dimethylimidazolium cation, a 1-ethyl-3-methylimidazolium cation (EMI⁺), a 1-methyl-3-propylimidazolium cation, a 1-butyl-3-methylimidazolium cation (BMI⁺), a 1-ethyl-3-propylimidazolium cation, and a 1-butyl-3-ethylimidazolium cation. Of these organic cations, imidazolium cations having a methyl group and a C₂₋₄ alkyl group, such as EMI⁺ and BMI⁺, are preferred.

When the molten salt electrolyte contains 90 mass % or more of a mixture of a sodium salt and another salt, and the salt other than the sodium salt is a salt of an organic cation and an anion, the concentration of sodium ions contained in the molten salt electrolyte (the same as the concentration of the sodium salt when the sodium salt is a monovalent salt) is preferably 2 mol % or more, more preferably 5 mol % or more, and still more preferably 8 mol % or more with respect to the amount of cations contained in the molten salt electrolyte. The concentration of sodium ions is preferably 30 mol % or less, more preferably 20 mol % or less, and still more preferably 15 mol % or less with respect to the amount of cations contained in the molten salt electrolyte. Such a molten salt electrolyte has a high ionic liquid content and a low viscosity and thus facilitates achievement of high capacity even in charging and discharging at a high current rate. The preferred range of the sodium ion concentration can be set by freely combining the preferred upper limit and lower limit of the sodium ion concentration described above. For example, the preferred range of the sodium ion concentration may be from 2 to 20 mol % or may be from 5 to 15 mol %.

From the standpoint of the balance among the melting point, the viscosity, and the ionic conductivity of the molten salt electrolyte, the molar ratio of the sodium salt to the salt of an organic cation and an anion is, for example, 2/98 to 20/80 and preferably 5/95 to 15/85.

Examples of alkali metal cations other than a sodium cation may include lithium, potassium, rubidium, and cesium cations. These cations may be used alone or in combination of two or more.

When the molten salt electrolyte contains 90 mass % or more of a mixture of a sodium salt and another salt, and the salt other than the sodium salt is a salt of an alkali metal cation other than a sodium cation and an anion, the concentration of sodium ions contained in the molten salt electrolyte (corresponding to the concentration of the sodium salt when the sodium salt is a monovalent salt) is preferably 30 mol % or more and more preferably 40 mol % or more with respect to the amount of cations contained in the molten salt electrolyte. The concentration of sodium ions is preferably 70 mol % or less and more preferably 60 mol % or less with respect to the amount of cations contained in the molten salt electrolyte. Such a molten salt electrolyte has good ionic conductivity and thus facilitates achievement of high capacity in charging and discharging at a high current rate. The preferred range of the sodium ion concentration can be set by freely combining the preferred upper limit and lower limit of the sodium ion concentration. For example, the preferred range of the sodium ion concentration may be from 30 to 70 mol % or may be from 40 to 60 mol % with respect to the total amount of cations contained in the molten salt electrolyte.

More specifically, for a mixture of a sodium salt and a potassium salt, the molar ratio of the sodium salt/the potassium salt is, for example, preferably 45/55 to 65/35 and more preferably 50/50 to 60/40 from the standpoint of the balance among the melting point, the viscosity, and the ionic conductivity of the electrolyte.

Specific examples of the salt other than the sodium salt include a salt of MPPY+ and FSA⁻ (MPPY-FSA), a salt of MPPY⁺ and TFSA⁻ (MPPY-TFSA), a salt of a potassium ion and FSA⁻ (K-FSA), and salts of a potassium ion and PFSA⁻ (K-PFSA), such as potassium bis(trifluoromethylsulfonyl)amide (K-TFSA).

Specific examples of the molten salt electrolyte include:

(i) a molten salt electrolyte containing a salt of a sodium ion and FSA⁻ (Na-FSA) and a salt of MPPY⁺ and FSA⁻ (MPPY-FSA),

(ii) a molten salt electrolyte containing a salt of a sodium ion and TFSA⁻ (Na-TFSA) and a salt of MPPY⁺ and TFSA⁻ (MPPY-TFSA),

(iii) a molten salt electrolyte containing a salt of a sodium ion and FSA⁻ (Na-FSA) and a salt of a potassium ion and FSA⁻ (K-FSA), and

(iv) a molten salt electrolyte containing a salt of a sodium ion and TFSA⁻ (Na-TFSA) and a salt of a potassium ion and TFSA⁻ (K-TFSA).

The number of salts forming the ionic liquid is not limited to one or two. The ionic liquid may contain three or more salts. For example, the molten salt electrolyte may contain 90 mass % or more of a mixture of a first salt, a second salt, and a third salt, or the molten salt electrolyte may contain four or more salts including first to third salts.

### [Positive Electrode]

The positive electrode includes a positive electrode current collector and a positive electrode active material layer attached to the positive electrode current collector. The positive electrode active material layer contains a positive electrode active material as an essential component and may contain, for example, a conductive carbon material and a binder as optional components. An example of the positive electrode used in a sodium-ion secondary battery, which is a nonaqueous electrolyte secondary battery, is described below, but the present invention is not limited to this positive electrode.

In a nonaqueous electrolyte secondary battery, a positive electrode active material exchanges electrons with alkali metal ions (sodium ions for a sodium-ion secondary battery and lithium ions for a lithium-ion secondary battery, hereinafter collectively referred to as alkali metal ions) (Faradaic reaction). Therefore, a positive electrode active material for a sodium-ion secondary battery is any material that electrochemically intercalates and deintercalates sodium ions. In particular, sodium-containing metal oxides are preferably used. Sodium-containing metal oxides may be used alone or in combination of two or more. The average particle size of sodium-containing metal oxide particles is preferably 2 μm or more and 20 μm or less.

For example, sodium chromite (NaCrO₂) can be used as a sodium-containing metal oxide. In sodium chromite, Cr or Na may partially be substituted by another element. For example, compounds represented by a general formula of Na₁₋ₓM¹ₓCr_{1-y}M²_{y}O₂ (0≦x≦2/3, 0≦y≦0.7, M¹ and M² each independently represent a metal element other than Cr and Na) are preferred. In the general formula, x more preferably satisfies 0≦x≦0.5, and M¹ and M² preferably represent, for example, at least one selected from the group consisting of Ni, Co, Mn, Fe, and Al. Here, M¹ is an element occupying a Na site and M² is an element occupying a Cr site. Such compounds can be produced with low costs and achieves good reversibility of the structural change associated with charging and discharging. A sodium-ion secondary battery having excellent charge/discharge cycle characteristics can be obtained accordingly.

Sodium iron manganese oxide (e.g., Na_{2/3}Fe_{1/3}Mn_{2/3}O₂) can also be used as a sodium-containing metal oxide. In sodium iron manganese oxide, Fe, Mn, or Na may partially be substituted by another element. For example, compounds represented by a general formula of Na_{2/3-x}M³ₓFe_{1/3-y}Mn_{2/3-z}M⁴_{y+z}O₂ (0≦x<2/3, 0≦y<1/3, 0≦z≦1/3, M³ and M⁴ each independently represent a metal element other than Fe, Mn, and Na) are preferred. In the general formula, x more preferably satisfies 0≦x≦1/3. M³ preferably represents, for example, at least one selected from the group consisting of Ni, Co, and Al. M⁴ preferably represents at least one selected from the group consisting of Ni, Co, and Al. Here, M³ is an element occupying a Na site and M⁴ is an element occupying a Fe or Mn site.

Examples of sodium-containing metal oxides that can be used include Na₂FePO₄F, NaVPO₄F, NaCoPO₄, NaNiPO₄, NaMnPO₄, NaMn_{1.5}Ni_{0.5}O₄, and NaMn_{0.5}Ni_{0.5}O₂.

Examples of conductive carbon materials to be contained in the positive electrode include graphite, carbon black, and carbon fiber. Of conductive carbon materials, carbon black is particularly preferred because good conducting paths are easily formed with a small amount of carbon black. Examples of carbon black include acetylene black, Ketjenblack, and thermal black. The amount of the conductive carbon material is preferably 2 to 15 parts by mass and more preferably 3 to 8 parts by mass with respect to 100 parts by mass of the positive electrode active material.

The binder has the functions of bonding the positive electrode active materials to each other and fixing the positive electrode active material to the positive electrode current collector. Examples of the binder that can be used include fluororesins, polyamide, polyimide, and polyamide-imide. Examples of the fluororesins that can be used include polyvinylidene fluoride (PVDF), polytetrafluoroethylene (PTFE), tetrafluoroethylene-hexafluoropropylene copolymers, and vinylidene fluoride-hexafluoropropylene copolymers. The amount of the binder is preferably 1 to 10 parts by mass and more preferably 3 to 5 parts by mass with respect to 100 parts by mass of the positive electrode active material.

As the positive electrode current collector, for example, a metal foil, a nonwoven fabric of metal fiber, or a metal porous sheet is used. A metal constituting the positive electrode current collector is preferably, but not necessarily, aluminum or an aluminum alloy because of its stability at a positive electrode potential. When an aluminum alloy is used, the aluminum alloy preferably contains 0.5 mass % or less of a metal component (e.g., Fe, Si, Ni, or Mn) other than aluminum. The thickness of the metal foil serving as the positive electrode current collector is, for example, 10 to 50 μm. The thickness of the nonwoven fabric of metal fiber or the metal porous sheet is, for example, 100 to 600 μm. The positive electrode current collector may be provided with a lead piece 2c for current collection (see FIG. 2). The lead piece 2c may be integrated with the positive electrode current collector as illustrated in FIG. 2, or a lead piece separately formed may be connected to the positive electrode current collector by welding or the like.

In an alkali metal ion capacitor, a positive electrode active material does not exchange electrons with alkali metal ions, but physically adsorbs and desorbs alkali metal ions (non-Faradaic reaction). Therefore, a positive electrode active material in an alkali metal ion capacitor is any material that can physically adsorb and desorb anions or alkali metal ions. In particular, carbon materials are preferred. Examples of carbon materials may include activated carbon, mesoporous carbon, microporous carbon, and carbon nanotubes. Such carbon materials may be activated or may not be activated. These carbon materials may be used alone or in combination of two or more. Of these carbon materials, for example, activated carbon and microporous carbon are preferred. As a conductive assistant, a binder, and a positive electrode current collector, the same materials as those described for the sodium-ion secondary battery can be used.

### [Negative Electrode]

The negative electrode includes a negative electrode current collector and a negative electrode active material layer attached to the negative electrode current collector. The negative electrode active material layer contains a negative electrode active material as an essential component and may contain, for example, a conductive carbon material and a binder as optional components. An example of the negative electrode used in a sodium-ion secondary battery is described below, but the present invention is not limited to this negative electrode.

In a nonaqueous electrolyte secondary battery, a negative electrode active material exchanges electrons with alkali metal ions (Faradaic reaction). Therefore, a metal to be alloyed with sodium or a material that electrochemically intercalates and deintercalates sodium ions can be used as a negative electrode active material for a sodium-ion secondary battery. Examples of the metal to be alloyed with sodium include metal sodium, sodium alloys, zinc, zinc alloys, tin, tin alloys, silicon, and silicon alloys. Of these metals, zinc and zinc alloys are preferred from the viewpoint of good wettability with the molten salt. The thickness of the negative electrode active material layer is preferably, for example, 0.05 to 1 μm. The amount of a metal component (e.g., Fe, Ni, Si, Mn) other than zinc or tin in zinc alloys or tin alloys is preferably 0.5 mass % or less.

When these materials are used, the negative electrode active material layer can be obtained by, for example, attaching or pressure-bonding a metal sheet to the negative electrode current collector. Alternatively, a metal may be gasified and applied to the negative electrode current collector by a vapor phase method, such as a vacuum deposition method or a sputtering method, or fine metal particles may be applied to the negative electrode current collector by an electrochemical method, such as a plating method. The vapor phase method or the plating method enables formation of a thin, uniform negative electrode active material layer.

As the material that electrochemically intercalates and deintercalates sodium ions, for example, a sodium-containing titanium compound or non-graphitizable carbon (hard carbon) is preferably used from the viewpoint of thermal stability and electrochemical stability. A preferred sodium-containing titanium compound is sodium titanium oxide. More specifically, at least one selected from the group consisting of Na₂Ti₃O₇ and Na₄Ti₅O₁₂ is preferably used. In sodium titanium oxide, Ti or Na may partially be substituted by another element. Examples of compounds that can be used include Na₂₋ₓM⁵ₓTi_{3-y}M⁶_{y}O₇ (0≦x≦3/2, 0≦y≦8/3, M⁵ and M⁶ each independently represent a metal element other than Ti and Na, for example, at least one selected from the group consisting of Ni, Co, Mn, Fe, Al, and Cr), and Na₄₋ₓM⁷ₓTi_{5-y}M⁸_{y}O₁₂ (0≦x≦11/3, 0≦y≦14/3, M⁷ and M⁸ each independently represent a metal element other than Ti and Na, for example, at least one selected from the group consisting of Ni, Co, Mn, Fe, Al, and Cr). The sodium-containing titanium compound may be used alone or in combination of two or more. The sodium-containing titanium compound may be used in combination with non-graphitizable carbon. Here, M⁵ and M⁷ are elements occupying a Na site and M⁶ and M⁸ are elements occupying a Ti site.

Non-graphitizable carbon refers to a carbon material that does not develop a graphite structure even by performing heating in an inert atmosphere and that contains fine graphite crystals oriented in random directions such that nanometer-scale voids are formed between crystal layers. Since the diameter of sodium ions, which are typical alkali metal ions, is 0.95 angstroms, the size of the voids is preferably sufficiently larger than this diameter. The average particle size of the non-graphitizable carbon (particle size D50 at the 50% cumulative volume in the volume particle size distribution) may be, for example, 3 to 20 μm, and is preferably 5 to 15 μm in order to enhance the filling property of the negative electrode active material in the negative electrode and to avoid side reactions with the electrolyte (molten salt). The specific surface area of the non-graphitizable carbon may be, for example, 1 to 10 m²/g and is preferably 3 to 8 m²/g in order to ensure sodium ion acceptability and avoid side reactions with the electrolyte. The non-graphitizable carbon may be used alone or in combination of two or more.

As a binder and a conductive material used in the negative electrode, the same materials as those described for the components of the positive electrode can be used. The amount of the binder is preferably 1 to 10 parts by mass and more preferably 3 to 5 parts by mass with respect to 100 parts by mass of the negative electrode active material. The amount of the conductive material is preferably 5 to 15 parts by mass and more preferably 5 to 10 parts by mass with respect to 100 parts by mass of the negative electrode active material.

As the negative electrode current collector, for example, a metal foil, a nonwoven fabric of metal fiber, or a metal porous sheet is used. A metal does not alloy with sodium can be used as the metal. In particular, for example, aluminum, aluminum alloys, copper, copper alloys, nickel, and nickel alloys are preferred because of their stability at a negative electrode potential. Of these, aluminum and aluminum alloys are preferred because of light-weightness. Examples of aluminum alloys that may be used include the same aluminum alloys as those described for the positive electrode current collector. The thickness of the metal foil serving as the negative electrode current collector is, for example, 10 to 50 μm. The thickness of the nonwoven fabric of metal fiber or the metal porous sheet is, for example, 100 to 600 μm. The negative electrode current collector may be provided with a lead piece 3c for current collection (see FIG. 2). The lead piece 3c may be integrated with the negative electrode current collector as illustrated in FIG. 2, or a lead piece separately formed may be connected to the negative electrode current collector by welding or the like.

An example of a preferred form of the negative electrode is a negative electrode that includes a negative electrode current collector formed of aluminum or an aluminum alloy and a negative electrode active material layer that is formed of zinc, a zinc alloy, tin, or a tin alloy and that covers at least a portion of the surface of the negative electrode current collector. This negative electrode has a high capacity and is unlikely to deteriorate over a long period of time.

In an alkali metal ion capacitor, a negative electrode active material exchanges electrons with alkali metal ions (Faradaic reaction). Therefore, a negative electrode active material in an alkali metal ion capacitor is any material that electrochemically intercalates and deintercalates alkali metal ions. Examples of the negative electrode active material used in a sodium-ion capacitor include the same negative electrode active materials as those described for the sodium-ion secondary battery. Examples of the negative electrode active material used in a lithium-ion capacitor include carbon materials, lithium-containing titanium compounds, silicon oxide, silicon alloys, zinc, zinc alloys, tin oxide, and tin alloys.

Examples of carbon materials may include graphite, graphitizable carbon (soft carbon), and non-graphitizable carbon (hard carbon). These carbon materials may be used alone or in combination of two or more. Of these carbon materials, graphite and/or hard carbon is preferred from the viewpoint of thermal stability and electrochemical stability.

A preferred lithium-containing titanium compound is lithium titanium oxide. Specifically, at least one selected from the group consisting of Li₂Ti₃O₇ and Li₄Ti₅O₁₂ is preferably used. In lithium titanium oxide, Ti or Na may partially be substituted by another element. For example, Li₂₋ₓM⁹ₓTi_{3-y}M¹⁰_{y}O₇ (0≦x≦3/2, 0≦y≦8/3, M⁹ and M¹⁰ each independently represent a metal element other than Ti and Na, for example, at least one selected from the group consisting of Ni, Co, Mn, Fe, Al, and Cr), and Li₄₋ₓM¹¹ₓTi_{5-y}M¹²_{y}O₁₂ (0≦x≦11/3, 0≦y≦14/3, M¹¹ and M¹² each independently represent a metal element other than Ti and Na, for example, at least one selected from the group consisting of Ni, Co, Mn, Fe, Al, and Cr) can be used. The lithium-containing titanium compound may be used alone or in combination of two or more. The lithium-containing titanium compound may be used in combination with non-graphitizable carbon. Here, M⁹ and M¹¹ are elements occupying a Na site and M¹⁰ and M¹¹ are elements occupying a Ti site.

### [Separator]

A separator can be interposed between the positive electrode and the negative electrode. The material of the separator may be selected in view of the operational temperature of the electricity storage device. For example, glass fiber, a silica-containing polyolefin, a fluororesin, alumina, or polyphenylene sulfite (PPS) is preferably used in order to avoid side reactions with the electrolyte. In particular, a nonwoven fabric of glass fiber is preferred because it is inexpensive and highly heat resistant. A silica-containing polyolefin and alumina are preferred because of good heat resistance. A fluororesin and PPS are preferred because of their heat resistance and corrosion resistance. In particular, PPS has good resistance against fluorine contained in the molten salt.

The thickness of the separator is preferably 10 μm to 500 μm and more preferably 20 to 50 μm. This is because with the thickness in this range, internal short-circuiting can effectively be prevented and the volume ratio of the separator to the electrode group can be reduced, providing a high capacity density.

### [Electrode Group]

The electricity storage device is used in a state where the electrolyte and the electrode group including the positive electrodes and the negative electrodes are accommodated in a case, for example. The electrode group is formed by stacking or spirally winding the positive electrodes and the negative electrodes with the separators each interposed between the positive electrode and the negative electrode. In this case, a portion of the case can be used as a first external terminal by using a case made of metal and having either the positive or the negative electrodes electrically connected to the case. The other negative or positive electrodes are connected via a lead piece to a second external terminal that extends out from the case while being insulated from the case.

Next, the structure of a sodium-ion secondary battery according to an embodiment of the present invention will be described.

The structure of a sodium-ion secondary battery according to the present invention is not limited to the following structure.

FIG. 1 is a perspective view of a sodium-ion secondary battery 100 in which a case is partially cut out. FIG. 2 is a schematic longitudinal cross-sectional view taken along line II-II in FIG. 1.

The sodium-ion secondary battery 100 includes a stacked type electrode group 11, an electrolyte (not shown), and a prismatic aluminum battery case 10 that accommodates the electrode group 11 and the electrolyte. The battery case 10 includes a bottomed outer can 12 having a top opening and a sealing plate 13 that closes the top opening.

The opening edge portion 12A of the outer can and the sealing plate 13 are welded by the above-mentioned method. When the sodium-ion secondary battery 100 is assembled, the electrode group 11 is formed first and placed in the outer can 12 of the battery case 10.

Subsequently, the following process is performed: the outer can 12 and the sealing plate 13 are welded and then an electrolyte is introduced through a safety valve 16 or the like, so that the separators 1, the positive electrodes 2, and the negative electrodes 3 that constitute the electrode group 11 are impregnated with the electrolyte. Alternatively, the electrode group may be impregnated with the electrolyte and then the electrode group containing the electrolyte may be placed in the outer can 12, followed by welding the outer can 12 and the sealing plate 13.

An external positive electrode terminal 14 is provided near one side of the sealing plate 13 so as to penetrate through the sealing plate 13 while being insulated from the battery case 10, and an external negative electrode terminal 15 is provided near the other side of the sealing plate 13 so as to penetrate through the sealing plate 13 while being electrically connected to the battery case 10. At a center portion of the sealing plate 13, a safety valve 16 for releasing gas generated in the battery case 10 when the internal pressure of the battery case 10 increases is provided.

The stacked type electrode group 11 includes multiple positive electrodes 2, multiple negative electrodes 3, and multiple separators 1, all having a rectangular sheet-like shape, each separator being interposed between the positive electrode 2 and the negative electrode 3. In FIG. 2, the separator 1 is formed to have a bag-like shape so as to surround the positive electrode 2, but the separator is not limited to this shape. The positive electrodes 2 and the negative electrodes 3 are alternately arranged in a stacking direction in the electrode group 11.

A positive electrode lead piece 2c may be formed at one end of each positive electrode 2. The positive electrode lead pieces 2c of the positive electrodes 2 are bundled and connected to the external positive electrode terminal 14 provided on the sealing plate 13 of the battery case 10, and consequently the positive electrodes 2 are connected in parallel. Similarly, a negative electrode lead piece 3c may be formed at one end of each negative electrode 3. The negative electrode lead pieces 3c of the negative electrodes 3 are bundled and connected to the external negative electrode terminal 15 provided on the sealing plate 13, and consequently the negative electrodes 3 are connected in parallel. The bundle of the positive electrode lead pieces 2c and the bundle of the negative electrode lead pieces 3c are preferably located on the right side and the left side of one end face of the electrode group 11 with a space therebetween so as to avoid contacting the bundles.

The external positive electrode terminal 14 and the external negative electrode terminal 15 each have a columnar shape and at least a portion exposed to the outside has a threaded groove. A nut 7 is fitted into the threaded groove of each terminal and the nut 7 is fixed to the sealing plate 13 by screwing the nut 7. A flange 8 is provided at a portion of each terminal accommodated in the battery case and the flange 8 is fixed to the inner surface of the sealing plate 13 with a washer 9 interposed therebetween by screwing the nut 7.

### EXAMPLES

Next, the present invention will be described in more detail by way of Examples. However, the present invention is not limited to Examples described below.

### Example 1

### Outer Can

A bottomed prismatic outer can having a size of 38 mm×112 mm×150 mm was obtained from an aluminum plate having a thickness of 1.5 mm. Regarding the thickness of side walls of the outer can, the thickness of two side walls on the shorter sides was 1.1 mm and the thickness of two side walls on the longer sides was 0.9 mm.

### (Sealing Plate)

A sealing plate having a size of 37 mm×111 mm was cut out from an aluminum plate having a thickness of 1.5 mm by press working. Simultaneously, a recess (second recess 13B) having a taper angle (θₜ) of 45° and a length (T_{B}) of 0.25 mm in the thickness direction was formed in one surface of the periphery of the sealing plate, and a right-angled recess (first recess 13A) having a length (T_{A}) of 1.0 mm in the thickness direction and a length (W_{A}) of 0.5 mm in the horizontal direction was formed in the other surface of the periphery of the sealing plate. A sealing plate having a thickness (T_{T}) of 1.5 mm was obtained accordingly.

### (Production of Positive Electrode)

A positive electrode paste was prepared by dispersing 85 parts by mass of NaCrO₂ (positive electrode active material) having an average particle size of 10 μm, 10 parts by mass of acetylene black (conductive agent), and 5 parts by mass of polyvinylidene fluoride (binder) in N-methyl-2-pyrrolidone (NMP). The obtained positive electrode paste was applied to both surfaces of an aluminum foil having a thickness of 20 μm, dried well, and then rolled and, as a result, a positive electrode was formed which has positive electrode mixture layers having a thickness of 80 μm on both surfaces and thus has a total thickness of 180 μm.

The positive electrode was cut into ten rectangular pieces having a size of 100 mm×100 mm, and ten positive electrodes were prepared accordingly. A lead piece for current collection was formed at one side end of one side of each positive electrode. One of ten positive electrodes was an electrode having a positive electrode mixture layer only on one surface thereof

### (Production of Negative Electrode)

A zinc layer (second metal) having a thickness of 100 nm was formed on both surfaces of an aluminum foil (first metal) having a thickness of 10 μm by zinc plating, and a negative electrode having a total thickness of 10.2 μm was produced.

The negative electrode was cut into ten rectangular pieces having a size of 105 mm×105 mm, and ten negative electrodes were prepared accordingly. A lead piece for current collection was formed at one side end of one side of each negative electrode. One of ten negative electrodes was an electrode having a negative electrode active material layer only on one surface thereof.

### (Separator)

A separator made of a silica-containing polyolefin and having a thickness of 50 μm was prepared. The average pore size was 0.1 μm and the porosity was 70%. The separator was cut into 21 pieces having a size of 110×110 mm, and 21 separators were prepared accordingly.

### (Molten Salt Electrolyte)

A molten salt electrolyte including a mixture of sodium bis(fluorosulfonyl)amide (Na-FSA) and 1-methyl-1-propylpyrrolidinium-bis(fluorosulfonyl)amide (MPPY-FSA) at a molar ratio (sodium salt/ionic liquid) of 10:90 was prepared.

### (Assembly of Sodium-Ion Secondary Battery)

The positive electrodes, the negative electrodes, and the separators were dried well by performing heating at 90° C. or more under a reduced pressure of 0.3 Pa. Subsequently, an electrode group was produced by stacking the positives electrodes and the negative electrodes with the separators each interposed between the positive electrode and the negative electrode such that the positive electrode lead pieces overlapped each other, the negative electrode lead pieces overlap each other, and the bundle of the positive electrode lead pieces and the bundle of the negative electrode lead pieces were symmetrically positioned. Electrodes having an active material layer (mixture layer) only on one surface were disposed at one end and the other end of the electrode group in such a manner that the active material layer faced an electrode having a different polarity. Subsequently, separators were also disposed outside both ends of the electrode group, which was then placed in the outer can together with a molten salt.

Finally, the first recess of the sealing plate was fitted into the opening of the outer can and the outer can and the sealing plate were joined by laser welding. As a result, a sodium-ion secondary battery A having a nominal capacity of 1.8 Ah and having the structure as illustrated in FIGS. 1 and 2 was completed. Laser welding was performed on the boundary between the edge portion of the outer can and the sealing plate by irradiation with a laser beam using a fiber laser at an angle of 45° with respect to the thickness direction of the sealing plate under the conditions of an output of 950 w, a travel speed of 3 mm/sec, and a beam radius of 0.3 mm.

### Example 2

A sodium-ion secondary battery B was produced in the same manner as in Example 1 except that the travel speed of the laser beam was 5 mm/sec.

### Comparative Example 1

A sodium-ion secondary battery C was produced in the same manner as in Example 1 except that the second recess was not formed in the sealing plate.

### Comparative Example 2

A sodium-ion secondary battery D was produced in the same manner as in Example 2 except that the second recess was not formed in the sealing plate.

### [Evaluation 1] Joint Strength

A hole was made in the outer cans of the sodium-ion secondary batteries A to D. While gas (e.g., air or nitrogen gas) was introduced through the hole, the internal pressure at the fracture of a laser-welded part was measured. This internal pressure was evaluated as joint strength.

TABLE 1

| | Battery A | Battery B | Battery C | Battery D |
|---|---|---|---|---|
| Joint Strength | 1.1 | 0.9 | 0.5 | 0.6 |
| (MPa) | | | | |

### [Evaluation 2] Observation of Joint Surface

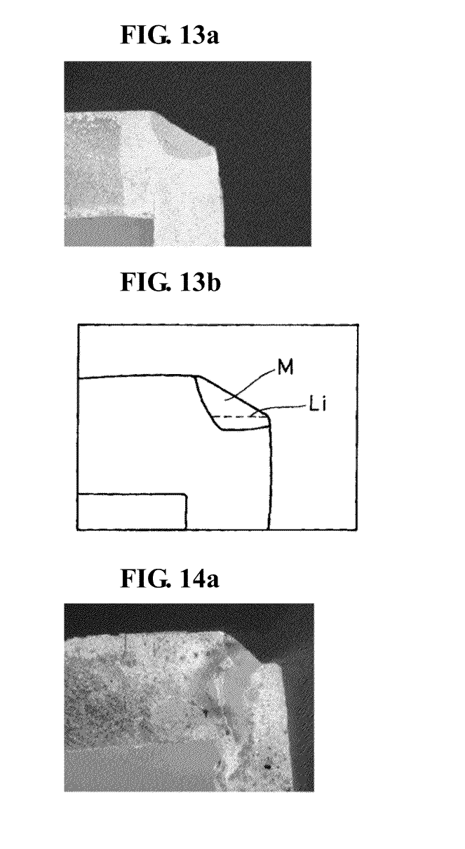

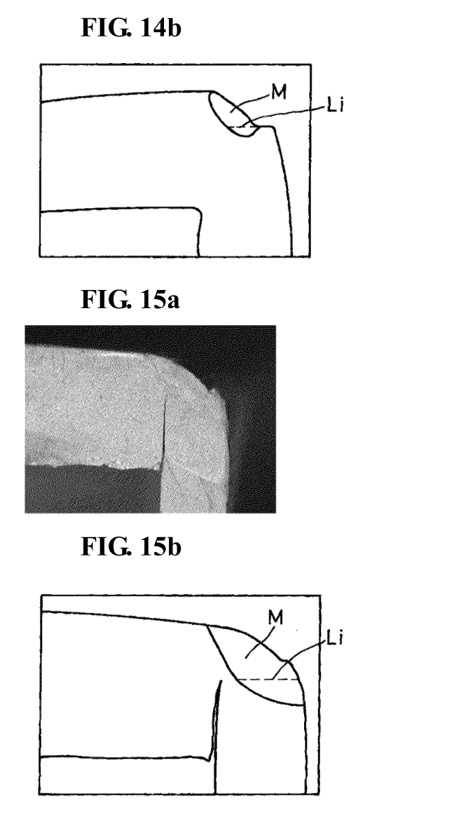

FIGS. 12a to 15a illustrate photographs (at a magnification of 18×) obtained by cutting the sodium-ion secondary batteries A to D at a section other than the corners and enlarging the joint portion between the outer can and the sealing plate. FIGS. 12b to 15b illustrate the traced drawings of the photographs. From the traced drawings, the width (Wⱼ) of the fusion part at the initial position (Lᵢ) and the fusion depth (d) were determined.

TABLE 2

| | Battery A | Battery B | Battery C | Battery D |
|---|---|---|---|---|
| Wⱼ (mm) | 0.84 | 0.72 | 0.54 | 0.60 |
| d (mm) | 0.12 | 0.17 | 0.17 | 0.4 |
| Wⱼ/d | 7.0 | 4.2 | 3.2 | 1.5 |

Although welding was performed on the batteries A and C under the same conditions and on the batteries B and D under the same conditions, a large difference in joint strength arose between the batteries A and C and between the batteries B and D. Moreover, the values of Wⱼ/d also notably differed.

These results indicate that with the second recess, good joint strength was obtained without increasing a laser output.

### Reference Example 1

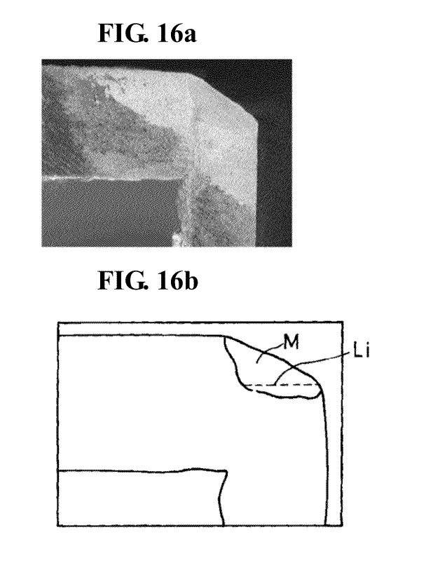

For comparison, a sodium-ion secondary battery E was produced in the same manner as in Example 1 except that the second recess was not formed in the sealing plate, the laser output was 990 w, and the travel speed of the laser beam was 3 mm/sec, and evaluated. FIG. 16a illustrates an enlarged photograph (at a magnification of 18×) of the sodium-ion secondary battery E. FIG. 16b is a traced drawing of the photograph.

The joint strength of the battery E was 0.9 MPa. This result indicates that the batteries A and B have a joint strength equal to or more than that of the battery E, which was obtained by welding at a higher laser output. The width (Wⱼ) of the fusion part was 0.73 mm, the fusion depth (d) was 0.18 mm, and Wⱼ/d was 4.1.

### INDUSTRIAL APPLICABILITY

The sealed type electricity storage device according to the present invention has good joint strength between the outer can and the sealing plate and therefore is useful in applications requiring long-term reliability, such as domestic or industrial large power storage apparatuses, and power sources for electric vehicles, hybrid vehicles, or the like.

### REFERENCE SIGNS LIST

1: Separator
2: Positive Electrode, 2c: Positive Electrode Lead Piece, 3: Negative Electrode, 3c: Negative Electrode Lead Piece
7: Nut, 8: Flange, 9: Washer, 10: Battery Case, 11: Electrode Group
12: Outer Can
12A: Opening Edge Portion of Outer Can, 12B: End Face of Opening Edge Portion of Outer Can
13: Sealing Plate
13A: First Recess, 13B: Second Recess, 13C: Erect Portion
14: External Positive Electrode Terminal, 15: External Negative Electrode Terminal,
16: Safety Valve
100: Sodium-Ion Secondary Battery

1. A method for producing a sealed type electricity storage device, comprising:
a step of preparing a bottomed outer can that accommodates an electrode group;
a step of preparing a sealing plate having a periphery corresponding to an opening of the outer can, the sealing plate having a first recess in one surface of the periphery and having a tapered second recess in the other surface of the periphery, the first recess being configured to fit into an opening edge portion of the outer can;
a step of closing the opening of the outer can with the sealing plate by fitting the first recess into the opening edge portion of the outer can; and
a step of welding the opening edge portion of the outer can and the periphery of the sealing plate by irradiating a boundary between the opening edge portion of the outer can and the periphery with a laser beam at an angle of 15° to 75° with respect to a thickness direction of the sealing plate.

2. The method for producing a sealed type electricity storage device according to claim 1, wherein the second recess is formed at an angle of 15° to 75° with respect to the thickness direction of the sealing plate.

3. The method for producing a sealed type electricity storage device according to claim 1, wherein the sealing plate has a thickness larger than a sum of a length of the first recess in the thickness direction of the sealing plate and a length of the second recess in the thickness direction of the sealing plate.

4. The method for producing a sealed type electricity storage device according to claim 1, wherein the sealing plate has a thickness of 0.5 to 3 mm, and a side wall of the outer can has a thickness of 0.5 to 3 mm.

5. The method for producing a sealed type electricity storage device according to claim 1, wherein a distance from the boundary to an outer surface of a side wall in the opening edge portion of the outer can is larger than a beam radius of the laser beam.

6. The method for producing a sealed type electricity storage device according to claim 1, wherein the laser beam used in irradiation has a beam radius of 0.1 to 0.5 mm.

7. A sealed type electricity storage device, comprising:
an electrode group;
a bottomed outer can that accommodates the electrode group; and
a sealing plate having a periphery corresponding to an opening of the outer can, wherein
an opening edge portion of the outer can and the periphery are welded to form a fusion part,
in a cross section of the fusion part parallel to a thickness direction of a side wall of the outer can and parallel to a thickness direction of the sealing plate,
a width Wⱼ of the fusion part at an initial position of the opening edge portion of the outer can and a maximum distance d from the initial position to an interface between the fusion part and a non-fusion part satisfy 3.5≦Wⱼ/d.
